(19) United States
(12) Patent Application Publication
(10) Pub. No.: US 2008/0122659 A1
(43) Pub. Date: May 29, 2008

(54) EMBEDDED CONTROLLER AND COMPUTER SYSTEM USING THE SAME

(75) Inventors: Ching-Min Hou, Taichung County (TW); Po-Cheng Chen, Tainan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ITE TECH. INC., Hsinchu (TW)

(21) Appl. No.: 11/672,966

(22) Filed: Feb. 9, 2007

(30) Foreign Application Priority Data
Nov. 23, 2006 (TW) 95143318

(51) Int. Cl. H03K 17/94

(52) U.S. Cl. 341/22

(57) ABSTRACT

An embedded controller includes a keyboard interface, a keyboard signal conversion unit, a flash memory control unit, and a selection unit. When the selection unit couples the flash memory control unit to the keyboard interface according to an indication signal, a remote controller is coupled to the keyboard interface so as to input an input signal to the embedded controller through the keyboard interface. And the flash memory control unit decodes the input signal and writes it into a flash memory to change a data stored in the flash memory.

### CROSS-REFERENCE TO RELATED APPLICATION

This application claims the priority benefit of Taiwan application serial no. 95143318, filed on Nov. 23, 2006. All disclosure of the Taiwan application is incorporated herein by reference.

### BACKGROUND OF THE INVENTION

1. Field of the Invention

The present invention relates to an embedded controller. More particularly, the present invention relates to an embedded controller disposed on a motherboard.

2. Description of Related Art

Flash memory is a common storage device on the motherboard, and has been widely applied in personal computers and notebook computers. The flash memory can store data of various types, and the data may be read or written through an embedded controller. In a computer system, the most widely used flash memory is the flash memory storing a base input/output system (BIOS).

FIG. 1 is a block diagram of a conventional circuit in the periphery of the BIOS on a motherboard. Referring to FIG. 1, the BIOS is stored in the flash memory 110 on the motherboard 100, and the flash memory 110 is coupled to the embedded controller 120, such that the flash memory control unit 124 in the embedded controller 120 can read and write the BIOS data in the flash memory 110.

The embedded controller 120 in FIG. 1 further includes a keyboard interface 122, a keyboard signal conversion unit 126, and a micro-processing unit 129. The keyboard interface 122 may be coupled to a keyboard or a keyboard matrix. After receiving the keyboard signal from the keyboard interface 122, the keyboard signal conversion unit 126 converts the keyboard signal into a data type that can be accepted by the micro-processing unit 129, and then outputs it to the micro-processing unit 129. Further, the motherboard 100 includes a south bridge chip 140, and is communicated with the embedded controller 120 through a low pin count bus (LPC bus).

In the conventional art, when the BIOS on the motherboard needs to be changed, a user or R&D engineer often takes out the flash memory on the motherboard directly, puts the flash memory in another burner to burn in a new BIOS, and then puts the flash memory back to the motherboard. Otherwise, the new BIOS is burned into the flash memory through a burning software or a utility under WINDOWS and DOS operating system.

However, during the R&D process or manufacturing process of products, such as notebook computers or motherboards, the BIOS is likely to be damaged due to the errors of test or system, and thus the BIOS on the motherboard needs to be changed. Since the damage of the BIOS may cause a failure in booting a computer system, the BIOS cannot be reburned through a burning software. Here, the motherboard of the notebook computer or desktop computer must be detached manually. The flash memory storing BIOS is pulled out, and the flash memory is put into the burner to refresh the BIOS.

In view of the above, those of ordinary skill in the art would understand that if it is required to take out the flash memory on the motherboard and put it on the burning table to perform burning, the R&D process of the product done by the engineer becomes quite complicated. Particularly, for a light, thin, short, and small notebook computer disassembly process would be very complicated. Therefore, if the above situation occurs during the manufacturing of the notebook computer, a batch of notebook computers in the production line needs to be dissembled to change the BIOS in flash memories, which wastes a great deal of time and manpower.

### SUMMARY OF THE INVENTION

Accordingly, the present invention is directed to an embedded controller, which enables a remote controller to update data stored in a flash memory through a keyboard interface.

The present invention is also directed to a computer system capable of updating the data in the flash memory through the keyboard interface, even when it is not started.

The present invention provides an embedded controller disposed on the motherboard and coupled to a flash memory. The embedded controller comprises a keyboard interface, a keyboard signal conversion unit, a flash memory control unit, and a selection unit. The keyboard signal conversion unit is used to convert the keyboard signal from the keyboard interface. The flash memory control unit is coupled to the flash memory, and updates the data in the flash memory according to the input signal received by the keyboard interface. The selection unit coupled to the keyboard interface is further coupled to the keyboard signal conversion unit and the flash memory control unit. The selection unit decides whether or not to couple the keyboard interface to the keyboard signal conversion unit or the flash memory control unit according to an indication signal of the keyboard interface.

According to a preferred embodiment of the present invention, the keyboard interface is coupled to a remote controller. When the indication signal of the keyboard interface controls the selection unit to couple the keyboard interface to the flash memory control unit, the remote controller inputs the input signal to the flash memory control unit, so as to update the data in the flash memory.

According to a preferred embodiment of the present invention, the remote controller is, for example, a personal computer, a notebook computer, a server, and the like. The remote controller comprises a generic interface, and is coupled to the keyboard interface through the generic interface. The generic interface is for example a parallel port interface.

According to a preferred embodiment of the present invention, the flash memory control unit comprises a decoder for decoding the input signal from the remote controller, so as to write the decoded input signal into the flash memory.

According to a preferred embodiment of the present invention, the embedded controller is coupled to a south bridge chip in the motherboard through a bus. Further, the embedded controller further comprises a micro-processing unit coupled to the keyboard signal conversion unit and the flash memory control unit, so as to control the operation of the embedded controller.

The present invention provides a computer system, which comprises a motherboard, a flash memory, and an embedded controller. The flash memory and the embedded controller are disposed on the motherboard, and the embedded controller is coupled to the flash memory and comprises a keyboard interface, a keyboard signal conversion unit, a flash memory control unit, and a selection unit. The keyboard signal conversion unit is used to convert the keyboard signal from the keyboard interface. The flash memory control unit is coupled to the flash memory, and updates the data in the flash memory according to the input signal received by the keyboard interface. The selection unit coupled to the keyboard interface is further coupled to the keyboard signal conversion unit and the flash memory control unit. The selection unit decides whether or not to couple the keyboard interface to the keyboard signal conversion unit or the flash memory control unit according to an indication signal of the keyboard interface.

According to a preferred embodiment of the present invention, the keyboard interface is coupled to a remote controller, wherein when the indication signal of the keyboard interface controls the selection unit to couple the keyboard interface to the flash memory control unit, the remote controller inputs the input signal to the flash memory control unit, so as to update the data in the flash memory.

According to a preferred embodiment of the present invention, the remote controller is, for example, a personal computer, a notebook computer, a server, and the like. The remote controller comprises a generic interface, and is coupled to the keyboard interface through the generic interface. The generic interface is, for example, a parallel port interface.

According to a preferred embodiment of the present invention, the flash memory control unit comprises a decoder for decoding the input signal from the remote controller, so as to write the decoded input signal into the flash memory.

According to a preferred embodiment of the present invention, the embedded controller is coupled to a south bridge chip in the motherboard through a bus. Further, the embedded controller further comprises a micro-processing unit coupled to the keyboard signal conversion unit and the flash memory control unit for controlling the operation of the embedded controller.

According to a preferred embodiment of the present invention, a BIOS is stored in the flash memory.

In the present invention, the flash memory control unit is coupled through the keyboard interface. Therefore, before the computer enters WINDOWS or DOS operating system, a remote controller is still used to change the data in the flash memory through the keyboard interface so that need of disassembling the computer that require additional man power may effectively eliminated.

In order to the make aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram of a conventional circuit in the periphery of a BIOS on a motherboard.

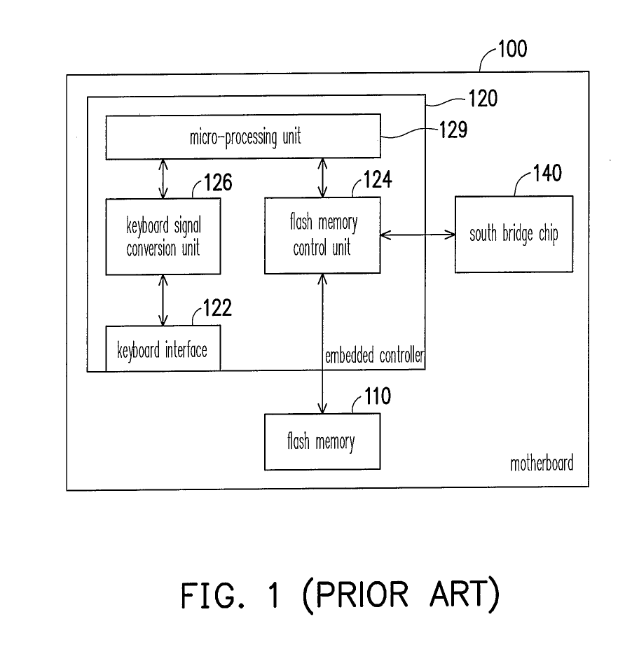

FIG. 2 is a block diagram of a circuit of a computer system according to an embodiment of the present invention.

FIG. 3 is a block diagram of a circuit of the computer system according to an embodiment of the present invention.

FIG. 4 is a block diagram of a circuit of the computer system according to an embodiment of the present invention.

### DESCRIPTION OF EMBODIMENTS

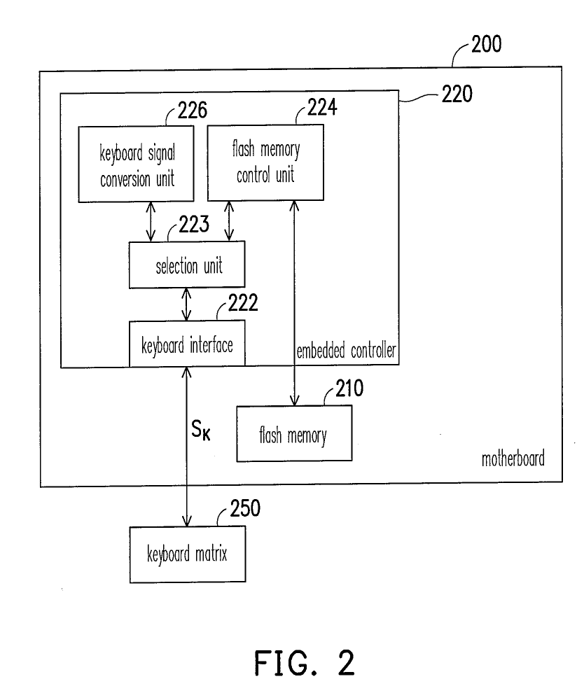

FIG. 2 is a block diagram of the circuit of a computer system according to an embodiment of the present invention. Referring to FIG. 2, the computer system includes a motherboard 200 and a keyboard matrix. In the embodiment of the present invention, the computer system is, for example, a notebook computer. The motherboard 200 includes a flash memory 210 and an embedded controller 220 provided by the embodiment of the present invention. It is assumed that a BIOS is stored in the flash memory 210. The embedded controller 220 provided by the embodiment of the present invention includes a keyboard interface 222, a selection unit 223, a flash memory control unit 224, and a keyboard signal conversion unit 226.

In a normal operating mode of the notebook computer, the keyboard interface 222 is coupled to the keyboard matrix 250. The user can use the embedded controller 220 to control the keyboard matrix 250 to convert the keyboard signal, so as to operate the notebook computer. In this embodiment, under the current technical specification, the keyboard interface 222 of the notebook computer has 24 pins among which 8 pins are undefined. The embedded controller 220 of this embodiment has an additional selection unit 223 compared to the embedded controller of the conventional art. Under normal operation, the keyboard interface 222 is coupled to the keyboard matrix 250, so that the 8 pins do not act. At this time, the selection unit 223 controls the keyboard interface 222 to be coupled to the keyboard signal conversion unit 226, so as to perform a general operation.

When the user presses keys in the keyboard matrix 250, the keyboard interface 222 receives a keyboard signal Sₖ from the keyboard matrix 250. The keyboard signal Sₖ is input to the keyboard signal conversion unit 226 through the selection unit 223. The keyboard signal conversion unit 226 converts the keyboard signal SK into a form that can be accepted by a back-end circuit (not shown), and then outputs it to the back-end circuit. In addition, the Rash memory control unit 224 in the embedded controller 220 reads and writes the data in the flash memory 210. For example, when the notebook computer is booted, the flash memory control unit 224 reads the BIOS stored in the flash memory 224, and outputs it to the back-end circuit (not shown), so as to execute power-on initial setting and test.

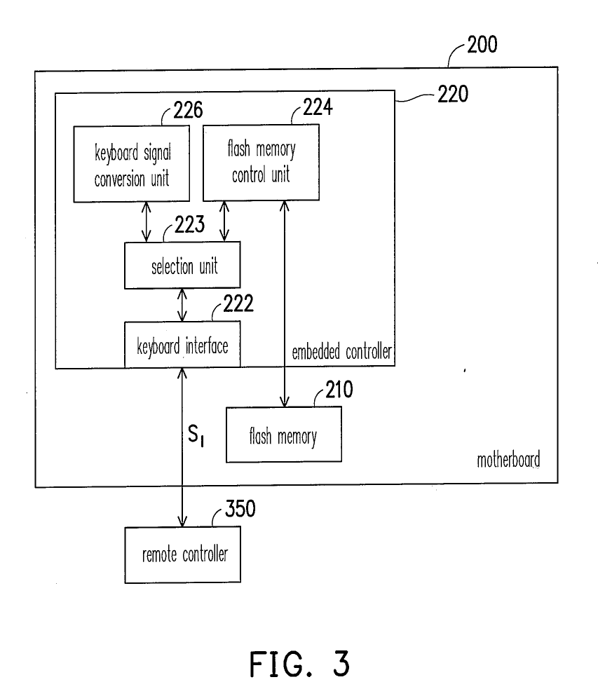

FIG. 3 is a block diagram of the circuit of the computer system according to an embodiment of the present invention. Referring to FIG. 3, in this embodiment, during the R&D or manufacturing process of the notebook computer, when the BIOS in the flash memory is lost and the computer cannot be booted, a worker can couple the keyboard interface 222 to a remote controller 350 to write new BIOS data into the flash memory 210 by using the embedded controller 220. Here, the remote controller 350 in FIG. 3 is, for example, a personal computer, a notebook computer, a server, and the like. The remote controller 350 is, for example, coupled to the keyboard interface 222 via a parallel port interface IEEE-1284 or other PC generic interfaces. The detailed description of usage of the embedded controller 220 to reflash the BIOS of the notebook computer will be illustrated as follows.

First, an operator uses the remote controller 350 to control a specific pin of the 8 undefined pins to input the indication signal into the embedded controller 220. When the selection unit 223 of the embedded controller 220 receives the indication signal through the specific pin, the keyboard interface 222 is coupled to the flash memory control unit 224 under control. Then, the operator uses the remote controller 350 to select the BIOS data to be reflashed and converts it into an input signal SI acceptable by the flash memory control unit 224. The flash memory control unit 224 includes a decoder which can decode the input signal SI into BIOS data. The flash memory control unit 224 writes the decoded data of the BIOS into the flash memory 210.

It can be known from the above embodiment that with the embedded controller of the embodiment of the present invention, when the computer is not started to enter DOS or WINDOWS operating system, a remote controller can be used to change the data in the flash memory through the keyboard interface. In practical application, since in the design of the mechanism, the keyboard interface is directly positioned under the keyboard matrix. Therefore, if it is found that the data in the flash memory needs to be changed after the notebook computer is assembled, the R&D or manufacturing engineer can change the flash memory data only by easily disassembling the keyboard matrix and using the keyboard interface. Compared with the conventional art, according to the embodiment of the present invention, the flash memory can be taken out without disassembling the entire notebook computer. Therefore, in the R&D and manufacturing process, a great deal of manpower and time can be saved, and the total manufacturing and R&D cost of the products can be reduced.

With reference to the operation of the selection unit 223, those of ordinary skill in the art would understand that in another embodiment, the selection unit 223 can be implemented by, for example, a multiplexer, wherein the control end of the multiplexer receives the indication signal and switches the keyboard interface 222 to be coupled to the keyboard signal conversion unit 226 or the flash memory control unit 224 according to the indication signal. In addition, it is not required to a build a decoder in the flash memory control unit 224. Those of ordinary skill in the art would understand that the software method can be used to achieve the same purpose, and the present invention is not limited there-to as such. Further, although the reflash of the BIOS is taken as an example for illustration in this embodiment, those of ordinary skill in the art would understand that all the flash memories coupled to the embedded controller can be implemented according to the method, and the present invention is not limited thereto as such.

It should be noted that although a possible form of the embedded controller and the computer system is described in this embodiment, those skilled in the art would understand that each manufacturer has a different design method for the embedded controller and computer system, so the application of the present invention is not limited to the possible form. In other words, as long as a selection unit is built in the embedded controller and the selection unit is used to couple the keyboard interface to the keyboard signal conversion unit or the flash memory control unit, it will conform to the spirit of the present invention.

Hereinafter, another embodiment is described, and those skilled in the art can implement the present invention with reference to the teaching of this embodiment.

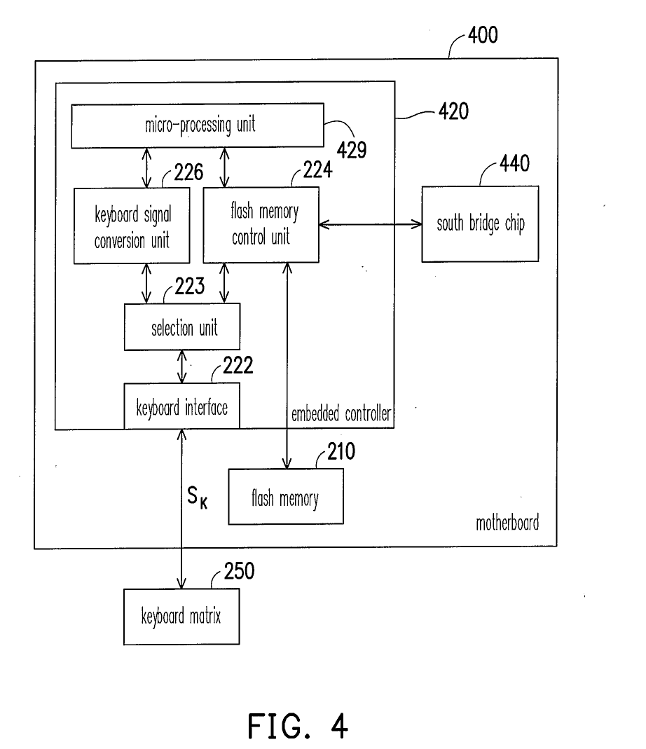

FIG. 4 is a block diagram of the circuit of the computer system according to an embodiment of the present invention. Referring to FIG. 4, the computer system includes a motherboard 400 and a keyboard matrix 250. The elements of the motherboard 400 are different from the elements of the motherboard 200 in FIG. 2 in terms of the micro-processing unit 429 and the south bridge chip 440 in the embedded controller 420. The micro-processing unit 429 is coupled to the keyboard signal conversion unit 226 and the flash memory control unit 224, so as to control the operation of the entire embedded controller 420.

The south bridge chip 440 is coupled to the flash memory control unit 224, and is communicated with the embedded controller 420 and transmits data and commands through an LPC bus. The south bridge chip 440 can also read the data in the flash memory 210 through the flash memory control unit 224. For example, when the notebook computer is booted, the BIOS in the flash memory 210 is transmitted to the south bridge chip, and then stored in Random Access Memory (RAM) in the computer through the south bridge chip. As the other elements in FIG. 4 are substantially the same as those in FIG. 2, the operating principle is similar, and therefore detail description thereof will not be repeated again.

In addition, in this embodiment, when the notebook computer cannot be booted to enter DOS or WINDOWS operating system and the data in the flash memory is required to be changed, according to the operation of the embodiment of FIG. 3, it is only required to couple the keyboard interface 222 on the motherboard to a remote controller and use the input signal of the remote controller to change the data in the flash memory.

To sum up, the embedded controller provided by the embodiment of the present invention enables a remote controller to input a signal to the flash memory through the keyboard interface. Therefore, when the computer cannot enter WINDOWS or DOS operating system, the keyboard interface can still be used to change the data in the flash memory, thus saving time and manpower required for disassembling the computer and taking out the flash memory.

It will be apparent to those skilled in the art that various modifications and variations can be made to the structure -of the present invention without departing from the scope or spirit of the invention. In view of the foregoing, it is intended that the present invention cover modifications and variations of this invention provided they fall within the scope of the following claims and their equivalents.

What is claimed is:

1. An embedded controller, disposed on a motherboard and coupled to a flash memory, comprising:
a keyboard interface;
a keyboard signal conversion unit, for converting a keyboard signal from the keyboard interface;
a flash memory control unit, coupled to the flash memory, for updating the data in the flash memory according to an input signal received by the keyboard interface; and
a selection unit, coupled to the keyboard interface, the keyboard signal conversion unit and the flash memory control unit, for deciding whether or not to couple the keyboard interface to the keyboard signal conversion unit or the flash memory control unit according to an indication signal of the keyboard interface.

2. The embedded controller as claimed in claim 1, wherein the keyboard interface is coupled to a remote controller, and wherein when the indication signal of the keyboard interface controls the selection unit to couple the keyboard interface to the flash memory control unit, the remote controller inputs an input signal to the flash memory control unit, so as to update data in the flash memory.

3. The embedded controller as claimed in claim 2, wherein the flash memory control unit comprises a decoder for decoding the input signal from the remote controller, so as to write the decoded input signal into the flash memory.

4. The embedded controller as claimed in claim 2, wherein the remote controller comprises a generic interface and is coupled to the keyboard interface through the generic interface.

5. The embedded controller as claimed in claim 4, wherein the generic interface is a parallel port interface.

6. The embedded controller as claimed in claim 2, wherein the remote controller is a personal computer, a notebook computer or a server.

7. The embedded controller as claimed in claim 1, further comprising a micro-processing unit coupled to the keyboard signal conversion unit and the flash memory control unit for controlling an operation of the embedded controller.

8. The embedded controller as claimed in claim 1, wherein the embedded controller is coupled to a south bridge chip in the motherboard through a bus.

9. The embedded controller as claimed in claim 1, wherein a basic input/output system (BIOS) is stored in the flash memory.

10. A computer system, comprising:
a motherboard;
a flash memory, disposed on the motherboard; and
an embedded controller, coupled to the flash memory, comprising:
a keyboard interface;
a keyboard signal conversion unit, for converting a keyboard signal from the keyboard interface;
a flash memory control unit, coupled to the flash memory, for updating the data in the flash memory according to an input signal of the keyboard interface; and
a selection unit, coupled to the keyboard interface, the keyboard signal conversion unit and the flash memory control unit, for deciding whether or not to couple the keyboard interface to the keyboard signal conversion unit or the flash memory control unit according to an indication signal of the keyboard interface.

11. The computer system as claimed in claim 10, wherein the keyboard interface is coupled to a remote controller, and wherein when the indication signal of the keyboard interface controls the selection unit to couple the keyboard interface to the flash memory control unit, the remote controller inputs an input signal to the flash memory control unit, so as to update the data in the flash memory.

12. The computer system as claimed in claim 11, wherein the flash memory control unit comprises a decoder for decoding the input signal from the remote controller, so as to write the decoded input signal to the flash memory.

13. The computer system as claimed in claim 11, wherein the remote controller comprises a generic interface and is coupled to the keyboard interface through the generic interface.

14. The computer system as claimed in claim 13, wherein the generic interface is a parallel port interface.

15. The computer system as claimed in claim 11, wherein the remote controller is a personal computer, a notebook computer or a server.

16. The computer system as claimed in claim 10, wherein the embedded controller further comprises a micro-processing unit coupled to the keyboard signal conversion unit and the flash memory control unit for controlling the operation of the embedded controller.

17. The computer system as claimed in claim 10, wherein the embedded controller is coupled to a south bridge chip in the motherboard through a bus.

18. The computer system as claimed in claim 10, wherein a basic input/output system (BIOS) is stored in the flash memory.
